(19) United States
(12) Patent Application Publication
(10) Pub. No.: US 2012/0125395 A1
(43) Pub. Date: May 24, 2012

(54) METHOD AND APPARATUS FACILITATING ELECTRICAL INTERCONNECTION OF A PLURALITY OF SOLAR MODULES

(75) Inventors: John Bellacicco, Stamford, CT (US); Tom Kuster, Clinton, NJ (US); Benyamin Buller, Perrysburg, OH (US); David Eaglesham, Perrysburg, OH (US)

(73) Assignee: FIRST SOLAR, INC, Perrysburg, OH (US)

(21) Appl. No.: 12/953,942

(22) Filed: Nov. 24, 2010

(51) Int. Cl. H01L 31/05; H01L 31/18

(52) U.S. Cl. 136/244; 29/890.033

(57) ABSTRACT

A method and apparatus to facilitate electrical interconnection of solar modules by using a wiring assembly having a plurality of conductors, each having one end connector and a plurality of spaced connection structures, each spaced structure for facilitating an electrical connection of at least one of the conductors with a respective solar module. The wiring assembly is mounted adjacent a plurality of solar modules such that the plurality of spaced connection structures are associated with respective electrical connections on a solar module to facilitate connection of the solar modules to the wiring assembly.

### FIELD OF THE INVENTION

Embodiments described herein relate to the electrical interconnection of a plurality of solar modules.

### BACKGROUND OF THE INVENTION

Photovoltaic power generating systems are currently constructed by installing a foundation system such as a series of posts or footings, a solar module structural support frame, which can involve brackets, tables or rails and clips for mounting individual solar modules to the support frame. The solar modules are electrically wired together into photovoltaic (PV) strings which strings are typically further wired together with other strings and connected to one or more aggregation points which are connected to electrical inverters in a PV system.

The wiring of individual solar modules can be time consuming and tedious, involving a considerable amount of manual labor. In addition, recently carrier systems have been proposed, as described, for example, in application Ser. No. 12/846,621 filed Jul. 29, 2010; application Ser. No. 12/846,644 filed Jul. 29, 2010; and application Ser. No. 12/846,686 filed Jul. 29, 2010, each of which is incorporated by reference in its entirety herein, for installing a plurality of solar modules onto a support system as a unit.

With innovations in PV modules, carriers and systems which make PV-generated energy more cost effective, there is a demand for increased efficiencies in installation of such systems. A simplified system for electrically interconnecting a plurality of solar modules is needed.

### BRIEF DESCRIPTION OF THE DRAWINGS

FIG. 1 illustrates a plan view of an embodiment in which a plurality of individual solar modules are electrically interconnected with a wiring assembly;

FIG. 2 illustrates a plan view of an embodiment in which a plurality of individual solar are electrically interconnected with a wiring assembly;

FIG. 3 illustrates in perspective view an embodiment of a carrier which supports a plurality of solar modules which may be electrically interconnected with a wiring assembly;

FIG. 4 illustrates in plan view the back side of the FIG. 3 carrier and associated wiring assemblies;

FIG. 5 illustrates in perspective view an embodiment of a portion of a wiring assembly;

FIG. 6A illustrates in cross-sectional view an embodiment of a portion of a wire assembly;

FIG. 6B illustrates in cross-sectional view another embodiment of a portion of a wiring assembly;

FIG. 6C illustrates in cross-sectional view another embodiment of a portion of a wiring assembly;

FIG. 7. illustrates in perspective view another embodiment of a portion of a wiring assembly;

FIG. 8 illustrates in perspective view another embodiment of a portion of a wiring assembly;

FIG. 9 illustrates in perspective view another embodiment of a portion of a wiring assembly;

FIG. 10 illustrates in perspective view another embodiment of a portion of a wiring assembly;

FIG. 11 illustrates in perspective view another embodiment of a portion of a wiring assembly;

FIG. 12 illustrates a cross-sectional view of the FIG. 11 embodiment;

FIG. 13 illustrates in cross-sectional view the FIG. 5 embodiment mounted on a solar module;

FIG. 14 illustrates in perspective view another embodiment of a portion of a wiring assembly mounted on a solar module;

FIG. 15 illustrates in cross-sectional view a modification of the FIG. 14 embodiment;

FIG. 16 illustrates in cross-sectional view a method of mounting the FIG. 14 embodiment on a solar module;

FIG. 17 illustrates a plan view of the FIG. 14 embodiment;

FIG. 18 illustrates in perspective view another embodiment of a portion of a wiring assembly;

FIG. 19 illustrates a plan view of the FIG. 18 embodiment;

FIG. 20 illustrates in end view a modification of the FIG. 14 embodiment;

FIG. 21 illustrates in end view another modification of the FIG. 14 embodiment;

FIG. 22 illustrates in end view another modification of the FIG. 14 embodiment;

FIG. 23 illustrates in end view another modification of the FIG. 14 embodiment;

FIG. 24A illustrates a portion of one method of mounting the embodiment of FIG. 14 to a solar module;

FIG. 24B illustrates another portion of the method of mounting the embodiment of FIG. 14 to a solar panel;

FIG. 24C illustrates another portion of the method of mounting the embodiment of FIG. 14 to a solar module;

FIG. 25 illustrates a modification of the wiring diagram of FIGS. 1 and 2 in which solar modules are connected in a star configuration; and

FIG. 26 illustrates another modification of the wiring diagram of FIGS. 1 and 2 in which solar modules are wired in series.

### DETAILED DESCRIPTION OF THE INVENTION

Embodiments disclosed herein provide a wiring assembly which can facilitate the interconnection of a plurality of solar panels in the field, as well as in a manufacturing facility where a plurality of solar modules may be aggregated together as a unit for installation.

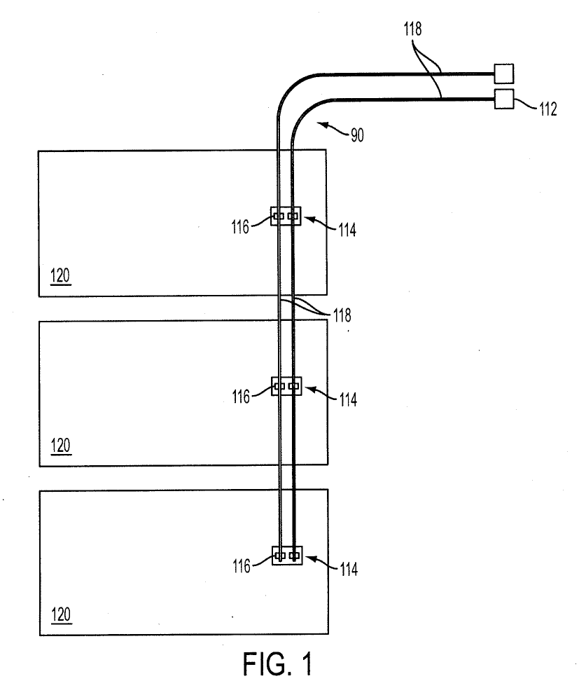

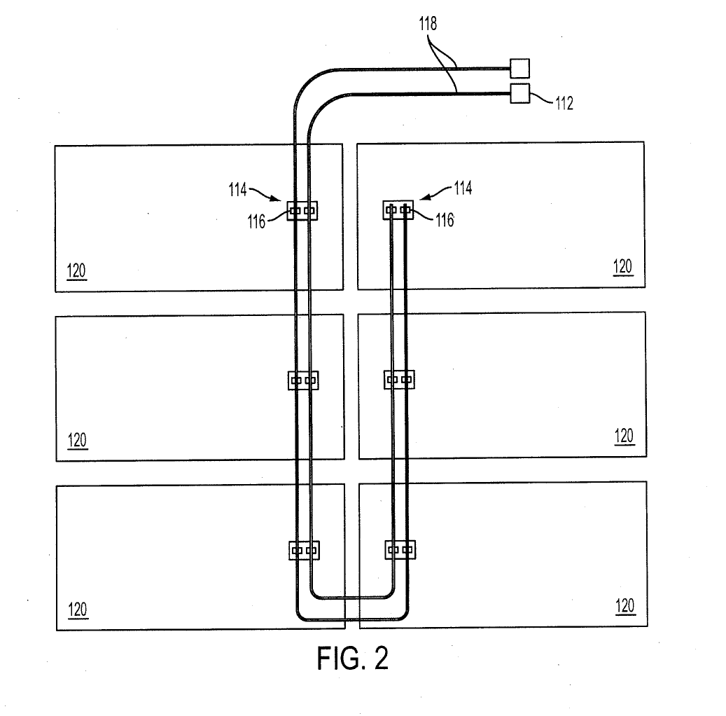

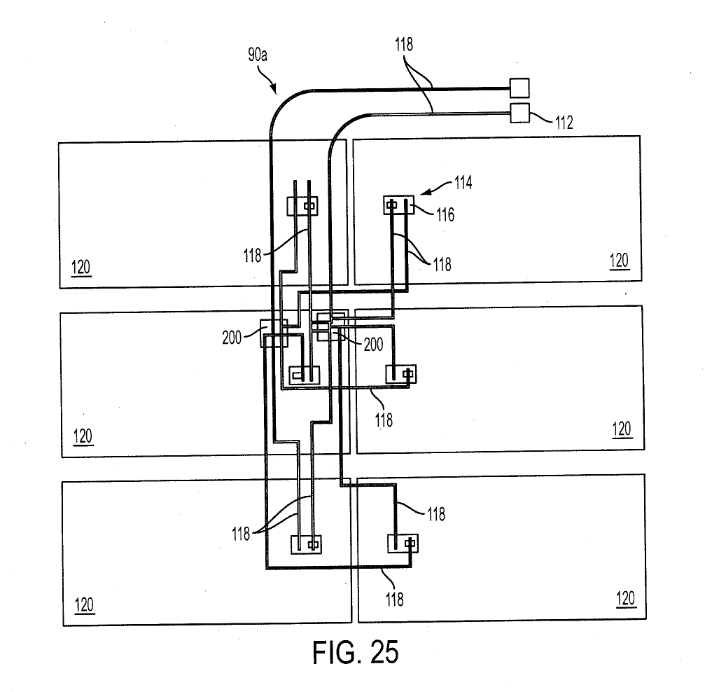

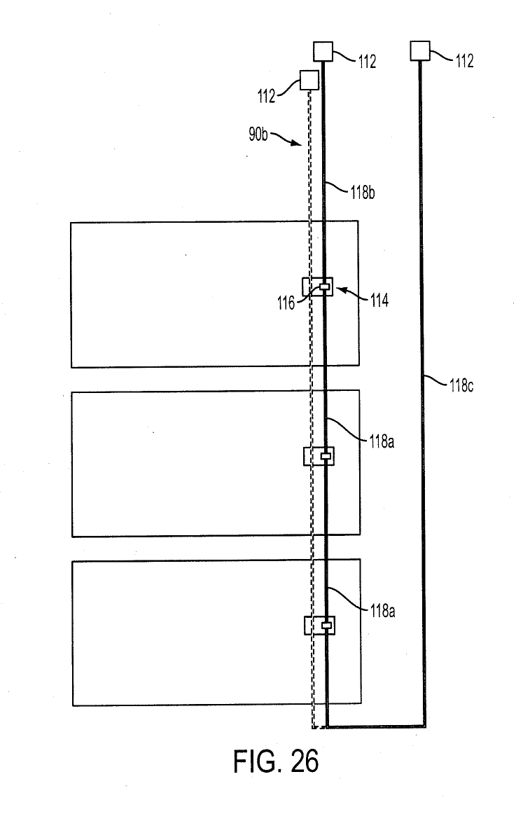

Referring first to FIG. 1, a wiring assembly 90 is illustrated in the form of a pair of conductors 118 which have at one terminating end thereof electrical connections 112. The electrical connections 112 may be in the form of terminating ends of the conductors 118 with or without electrical connectors attached thereto. The wiring assembly 90 also has at various locations spaced therealong connection areas 114 for making an electrical connection with a connection structure 116 of a solar module 120. FIG. 1 illustrates three solar modules which will be connected in parallel by the wiring assembly 90, but the number of solar modules can be any number as represented in FIG. 2 where six solar modules 120 are illustrated, all connected in parallel by the wiring assembly 90. Since each solar module 120 has a connection structure 116 which includes a positive and negative connection terminal, the wiring assembly 90 likewise has one of the conductors 118 as a positive conductor and the other conductor 118 as a negative conductor. Although FIGS. 1 and 2 illustrate a wiring assembly 90 which can be used to interconnect a plurality of modules 120 in parallel, wiring assembly 90 can also be arranged to electrically interconnect a plurality of modules in a star configuration or in series, or any other desired configuration. In FIGS. 25 and 26, a plurality of modules is shown to be interconnected in a star configuration and in series, respectively.

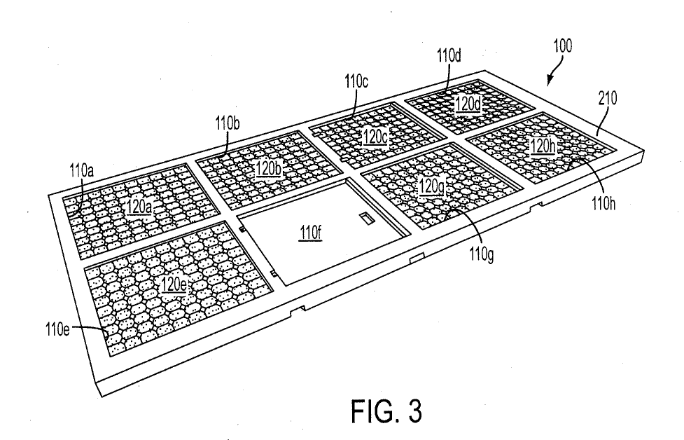

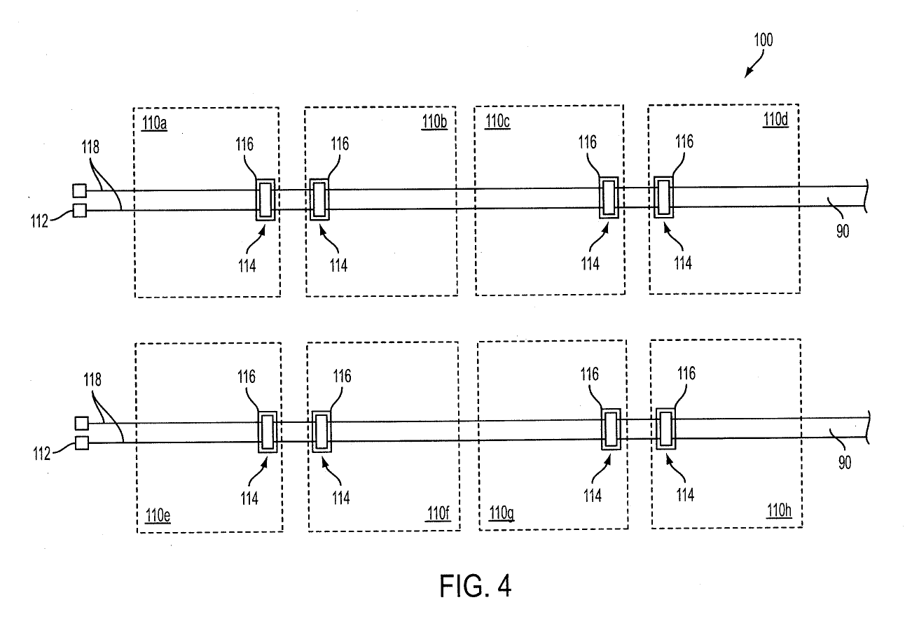

One example of the use of wiring assembly 90 is in connection with a carrier 100, shown in FIG. 3, which supports a plurality of solar modules 120a . . . 120h for installation as a unit. The carrier 100 illustrated in FIG. 3 is described in greater detail in U.S. application Ser. No. 12/846,621, filed Jul. 29, 2010, which has been incorporated herein by reference. Solar modules 120a . . . 120h have a corresponding connection structure 116 on the backside thereof, as illustrated in greater detail in FIG. 4. As shown in FIG. 4, the backsides 110a . . . 110h of the solar modules 120a . . . 120h have one or more wiring assemblies 90 for interconnecting the modules 120a . . . 120h. As shown in FIG. 4, one arrangement which may be employed is to wire modules 120a . . . 120d in a row in parallel using one wiring assembly 90 and wiring solar modules 120e . . . 120h of another row in parallel with a second wiring assembly 90. Although FIG. 4 illustrates the use of a plurality of wiring assemblies 90 in conjunction with a plurality of solar modules 120a . . . 120h provided on a carrier 100, the wiring assembly 90 may also be more generally employed to electrically interconnect any number of solar modules in a manufacturing facility or in a field installation. In addition, referring again to FIG. 4, one or more wiring assemblies 90 may be used to interconnect together rows of modules 120 as shown or columns of modules 120, or other combination of rows and columns of modules 120.

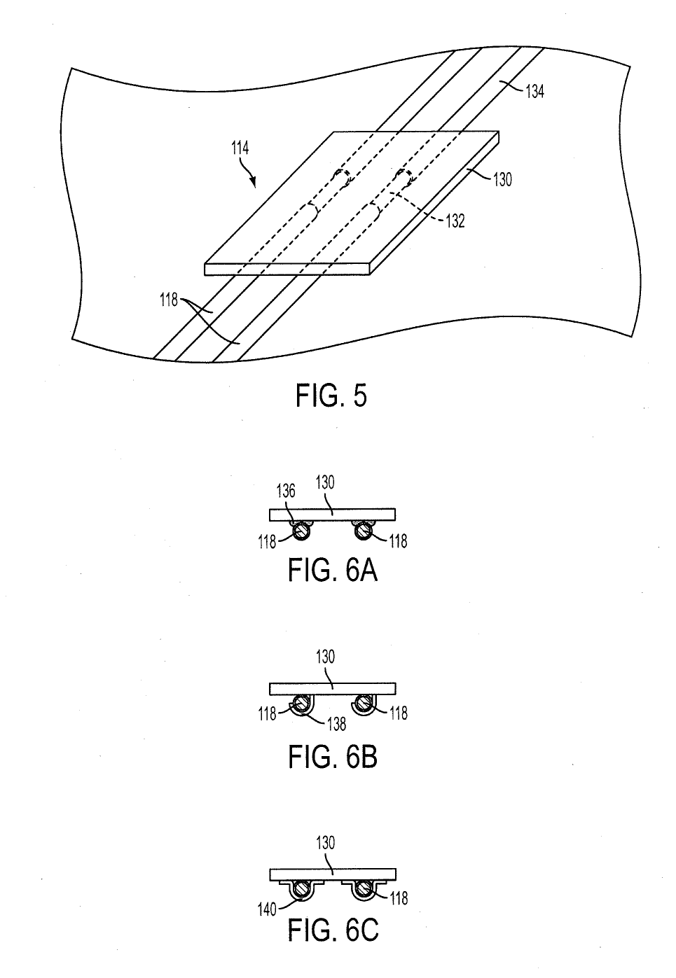

The spaced connection areas 114 provided along wiring assembly 90 will now be described with specific reference to various embodiments thereof illustrated in FIGS. 5-23. Referring first to FIG. 5, each of the connection areas 114 may be formed by conductors 118 attached to and spanning across a plate 130 formed of an insulating material. The plate 130 with attached conductors 118 is spaced along wiring assembly 90 and arranged such that the conductors 118 can be electrically connected to a connection structure 116 provided at a solar module 120. FIG. 5 illustrates the conductors 118 running beneath plate 130 and including an uninsulated portion 132 where the conductor is exposed and which may be electrically connected to solar module 120 electrical conductors 164 (FIG. 13) as described below in more detail. Remaining, insulated portions 134 of conductors 118 are also illustrated in FIG. 5.

As illustrated in FIG. 6A, the conductors 118 can be affixed to the connection plate 130 by an adhesive 136. In another embodiment, illustrated in FIG. 6B, J-hooks 138 can be provided affixed to the bottom side of plate 130 to hold the conductors 118 in place. In yet another embodiment illustrated in FIG. 6C, the conductors 118 may be held to the underside of plate 130 usingU-shaped clamps 140. The J-hooks 138 or clamps 140 may be fastened to the underside of plate 130 using adhesive, screws, bolts or any other suitable fastening elements.

FIG. 7 illustrates yet another embodiment in which the underside of plate 130 is now illustrated face up. Here, support elements 136 can be used to support the conductors 118 in a spaced manner away from plate 130. As illustrated in FIG. 7, the support elements 136 are provided at the uninsulated portion 132 of the conductors 118. This enables the conductors 118 otherwise affixed to plate 130 to be raised from the surface of plate 130 to place the uninsulated portions 132 in a more favorable position for connection to the electrical conductors 164 of a solar module (FIG. 13). Support elements 136 can be made of an insulating or conductive material and may be affixed to insulating plate 130, for example, by adhesive, screws, bolts or other suitable fastening elements.

Although FIG. 7 illustrates spaced support elements 136 provided at the uninsulated portion 132 of the conductors 118, the support elements 136 could also extend along the surface of plate 113 to the full extent that conductors 118 cross plate 130, as another alternative. Also, while a pair of spaced support elements 136 is illustrated, they can be combined to form a single support element to which both conductors 118 can be affixed, provided the single support element is formed of an insulating material.

As noted, the support elements 136 are affixed to the plate 130 by adhesive, screws, bolts or other suitable fastening elements. The conductors 118 may in turn affixed to the elements 136 and/or plate 130 using an adhesive 136 (FIG. 6A) or J-hooks or clamps described above with reference to FIGS. 6B, 6C. If separate support elements 136 are made of a weldable or solderable material, the uninsulated portion 132 of the conductors 118 can also be welded or soldered to the support elements 136.

FIG. 8 illustrates yet another embodiment in which plate 130 formed of an insulating material has affixed thereto two conductive supports 140 to allow for fixation of ends of discrete conductors 118a at each connection plate 130. Thus, wiring assembly 90 can be made from continuous conductors 118 as illustrated in FIG. 7, or segmented conductors 118a as illustrated in FIG. 8, the latter of which are electrically interconnected at the plate 130.

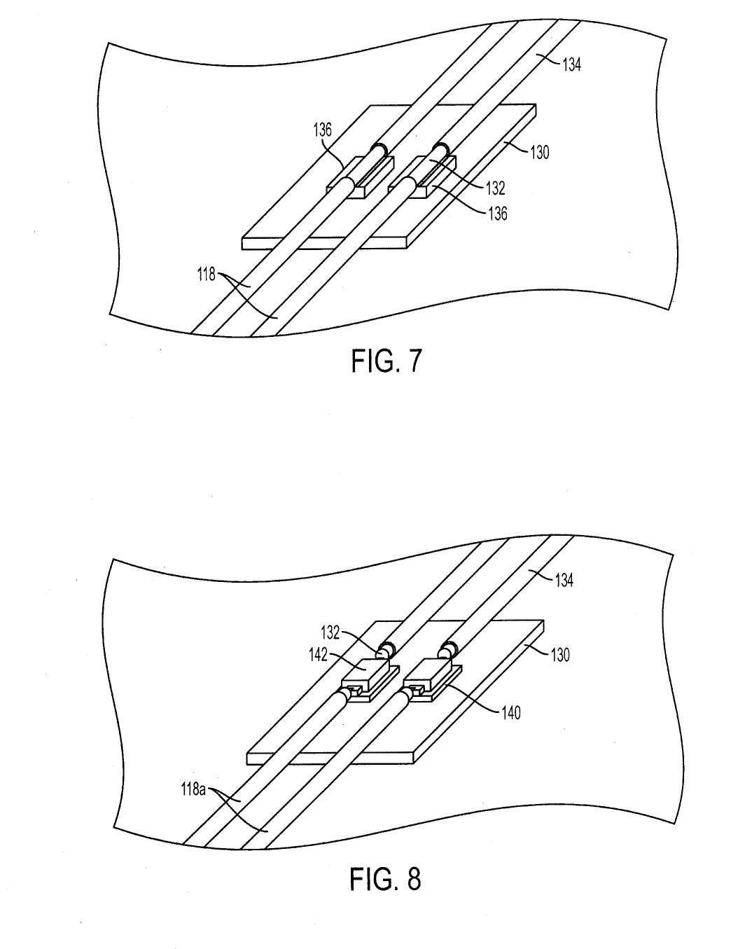

FIG. 9 illustrates yet another embodiment of a plate 130 formed of insulating material on which a conductive block 144 is affixed. Conductive block 144 has opposing insertion holes provided for each of the segmented conductors 118a. In this embodiment, the segmented conductors 118a have their terminating ends stripped and inserted into the conductive block where they are electrically affixed to the conductive block by soldering, welding, conductive adhesive or other means of electrical and mechanical connection.

FIG. 10 illustrates yet another embodiment of a plate 130a which may be used at a connection area 114. In this embodiment, plate 130a has grooves for accommodating the conductors 118 so that the conductors 118 are at least partially recessed within grooves 146 of the plate 130a. In this embodiment, only one conductor 118 is shown and it is a continuous conductor. However, segmented conductors 118a could also be used with grooved plate 130a in the manner illustrated in FIG. 8.

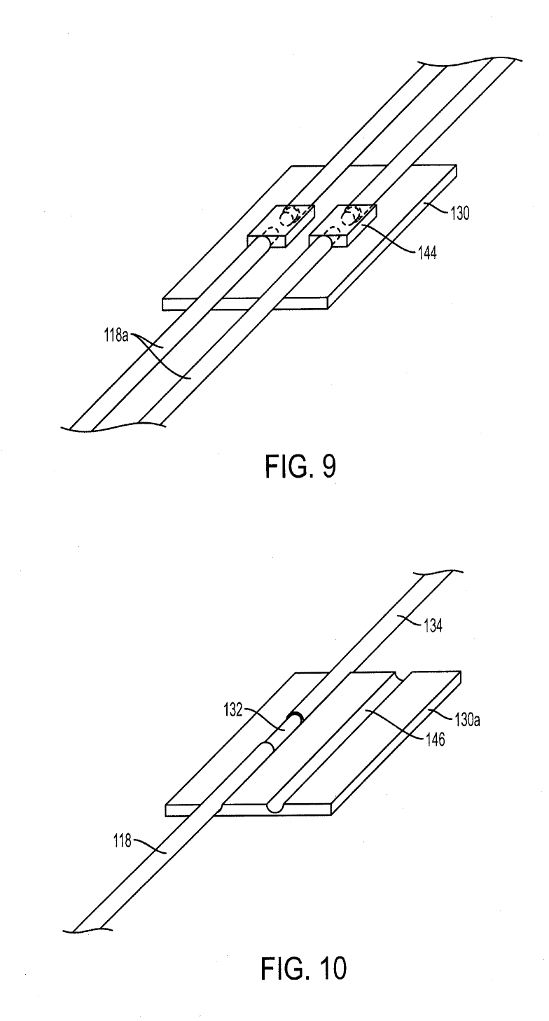

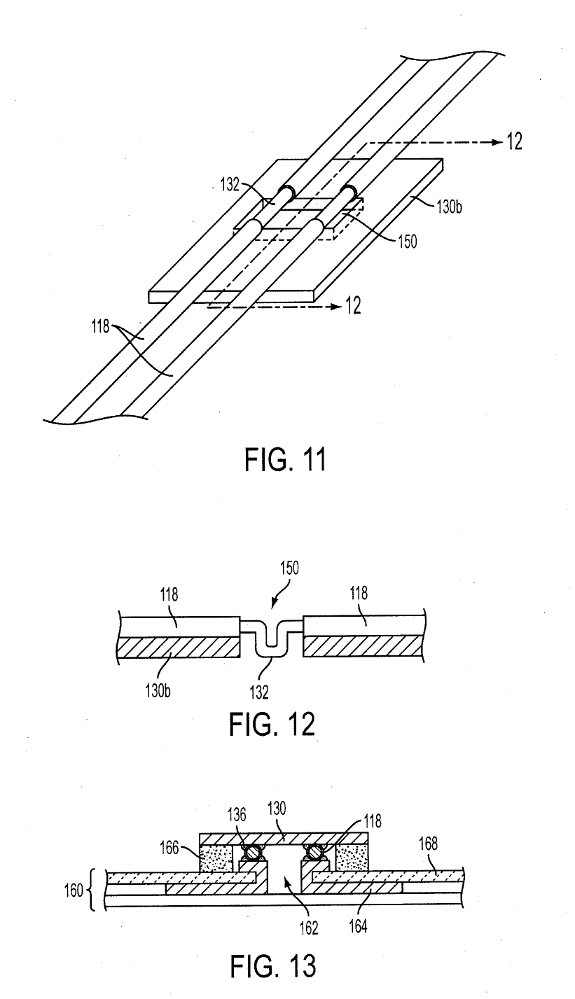

FIG. 11 illustrates another embodiment in which a plate 130b formed of an insulating material has an opening 150 therein. The conductors 118 span across the opening, and a portion of the conductors 118 which span across the opening has insulation removed to provide uninsulated portion 132. As an alternative to uninsulated portion 132 spanning across the opening, the opening 150 may be sized sufficiently to allow the uninsulated portion 132 of the conductors 118 to be pressed down and so that an outer surface thereof is substantially flush with the lower surface of plate 130b, as illustrated in the cross-sectional view of FIG. 12. This can facilitate connection of the uninsulated area 132 of the conductors 118b to the electrical conductors 164 (FIG. 13) of a solar module 120.

FIG. 13 illustrates an example of how the various embodiments illustrated in FIGS. 6A, 6B, 6C, 7, 8, 9, 10, 12 may be mounted to a solar module 120. The solar module 120 typically has as exterior panel glass 168 on a back side having one or more openings 162 through which a pair of solar module electrical conductors 164 pass. The solar module electrical conductors 164 can be bent back over an outer exterior surface of the panel glass 168. The electrical conductors 164 of the solar module 120 are connected internally to the solar cells of the module 120 and provide a module output voltage. One of the electrical conductors 164 is a positive conductor and the other is a negative conductor.

FIG. 13 shows how a plate 130, for example, that shown in FIG. 6A, is mounted such that the uninsulated portions 132 of the conductors 118 are mounted on respective module electrical conductors 164. It should be noted that the module electrical conductors 164 correspond to the module connection structure 116 illustrated in FIGS. 1 and 2. The uninsulated portion 132 of the conductors 118 can be welded, soldered, connected by a conductive adhesive, or otherwise mechanically and electrically connected to the solar module electrical conductors 164. The space around and beneath the peripheral edges of the plate 130 can then be sealed with a non-conductive filler material 166 which may be an adhesive, epoxy, molding compound, or other material which provides an uninsulated and adhesive connection of the plate 130 to the panel glass 168, as well a seal of the opening 162 of the panel glass 168. The filler material 166 surrounds the entire peripheral area of the opening 162 and is molded around the conductors 118, which then project through a portion of the filler material 166.

If the uninsulated portion 132 of conductors 118 is affixed to the solar module 120 electrical conductors 164 by welding, or soldering, a welding or soldering tool is inserted from the side edges and under plate 130 to perform the welding or soldering before the filler material 166 is applied.

The uninsulated portion 132 in each of the embodiments 6B, 6C, 7, 8, 9 and 10 can likewise have their plates 130, 130a, respectively, provided over the opening 162 of the solar module, with the uninsulated portions 132 of the conductors 118, or connection blocks, e.g. 144, to which the conductors are electrically connected, welded, soldered, adhesively connected with a conductive adhesive, or otherwise mechanically and electrically affixed to the module electrical conductors 164, following which the entire peripheral area beneath the plates 130, 130a is sealed with the filler material 166.

The embodiments of FIGS. 11 and 12 which have a hole 150 within the plate 130b can be directly adhesively affixed to the panel glass 168 by an adhesive, and the connection from the uninsulated portion 132 of conductors 118 to the module 120 electrical conductors 164 can be provided by welding, soldering, conductive adhesive, or other manner of mechanical and electrical affixation through opening 150 in the plate 130b. As illustrated in FIG. 12, the uninsulated portion 132 of the conductors 118 can be bent down towards the bottom surface of plate 130b to make it easier to make a mechanical and electrical connection between the uninsulated portions 132 and the module electrical conductors 164. With the FIGS. 11 and 12 embodiments, once the electrical connection to the module conductors 164 is made through the opening 150, the opening 150 may be filled with a filler material 166 to close and seal the hole 150, which also seals the opening 162 in the panel glass 168.

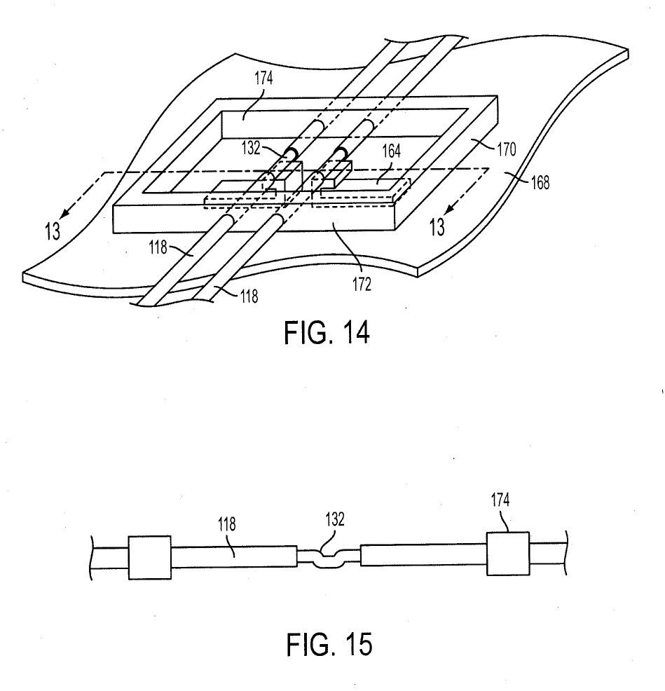

FIG. 14 illustrates another embodiment of a connection area 114 which may be used to interconnect the conductors 118 of the wiring assembly 90 to the conductors 164 of a solar module 120. In this embodiment, a housing 170 is provided which is sized to surround the opening 162 of a solar panel 120 shown, for example, in FIG. 13. The housing includes peripheral sidewalls 174, including opposing sidewalls, through which the conductors 118 pass. The housing 170 supports conductors 118, and the conductors 118 have an uninsulated portion 132 for connection with the module electrical conductors 164. The conductors 118 may span straight across the sidewalls of housing 170, or may have a bent section, illustrated in FIG. 15, where the uninsulated portion 132 of the conductors 118 is bent towards a bottom surface of the housing 170 to facilitate mechanical and electrical connection with the solar module electrical conductors 164.

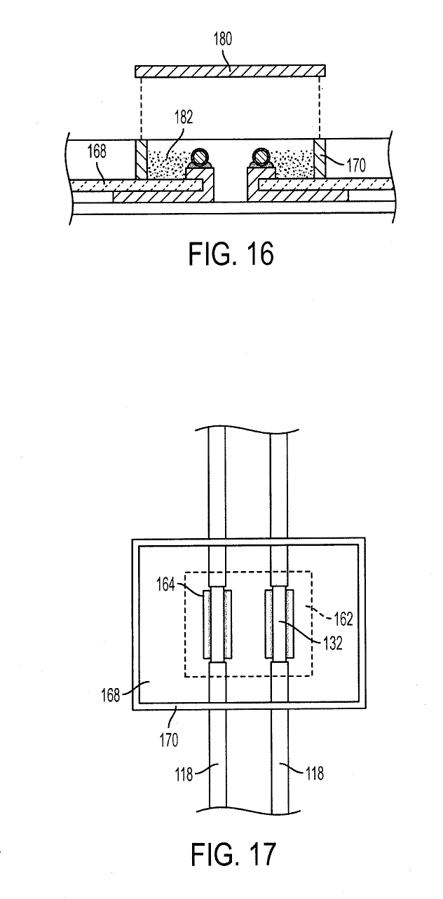

FIG. 16 illustrates how housing 170 is used to electrically connect the conductors 118 to the solar module electrical connectors 164. The housing 170 is placed on the panel glass 168 with the bottom surface of the housing being adhesively secured to the panel glass 168 in a manner which surrounds the opening 162 of a solar module 120. In this instance, conductors 118 can be welded, soldered, affixed with a conductive adhesive or affixed by other means of electrical and mechanical connection at the uninsulated portion 132 directly to the electrical conductors 164. Once the conductors 118 are electrically connected to the conductors 164, the interior cavity defined by the housing 170 sidewalls 174 can be filled with an insulating filler material 166 to seal the opening 162 of the solar module. Alternatively, or in addition to the filter material 166, and as shown in FIG. 16, a cover plate 180 can be used to cover the cavity housing 170, in which case the cover plate 180 is adhesively or otherwise mechanically affixed to the upper surface of housing 170.

FIG. 17 shows a plan view of housing 170 after it is affixed to the panel glass 168, and illustrates the open cavity defined by housing 170 through which the conductors 118 can be mechanically and electrically affixed to the module electrical conductors 164.

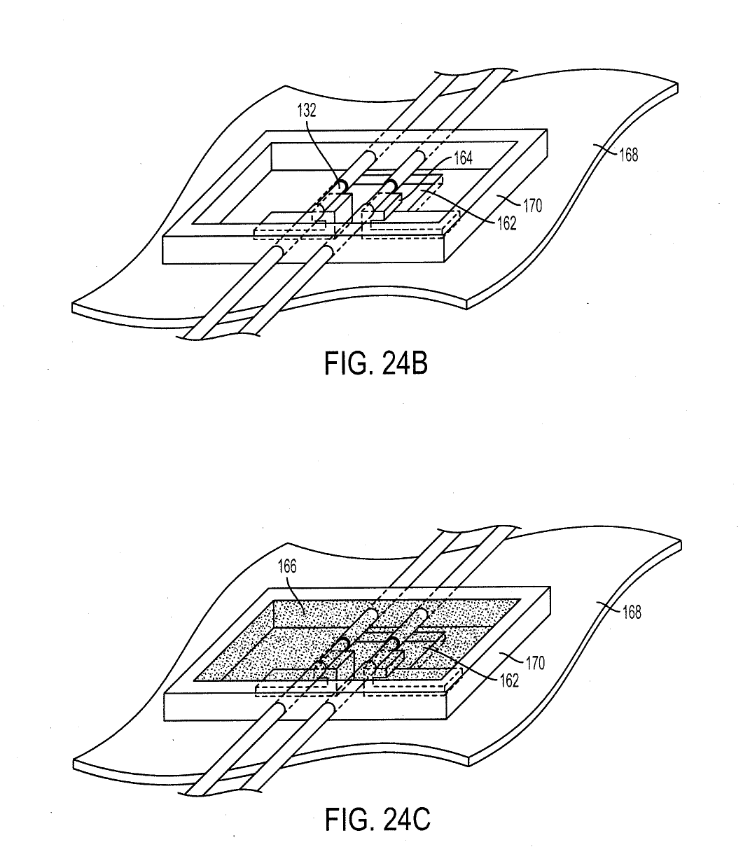

FIGS. 24A, 24B, 24C better illustrate the steps by which a housing 170, such as the one illustrated in the FIG. 14 embodiment, can be affixed to the outer surface of glass panel 168 and the conductors 118 mechanically and electrically affixed to module conductors 164. FIG. 24A shows housing 170 positioned over glass panel 168 to surround opening 162. FIG. 24B shows the housing 170 affixed, for example by an adhesive, to panel glass 168. FIG. 24B also shows how the uninsulated portion 132 of the conductors 118 can be mechanically and electrically affixed to the electrical connectors 164 of the module through the cavity defined by housing 170. FIG. 24C illustrates the filling of the cavity defined by housing 170 with an insulating filler material 166 after mechanical and electrical connection of the conductors 118 to the conductors 164. Furthermore, as noted, if desired, a cover (FIG. 16) can also be provided over and sealed to housing 170 in addition to or in lieu of the filler material 166.

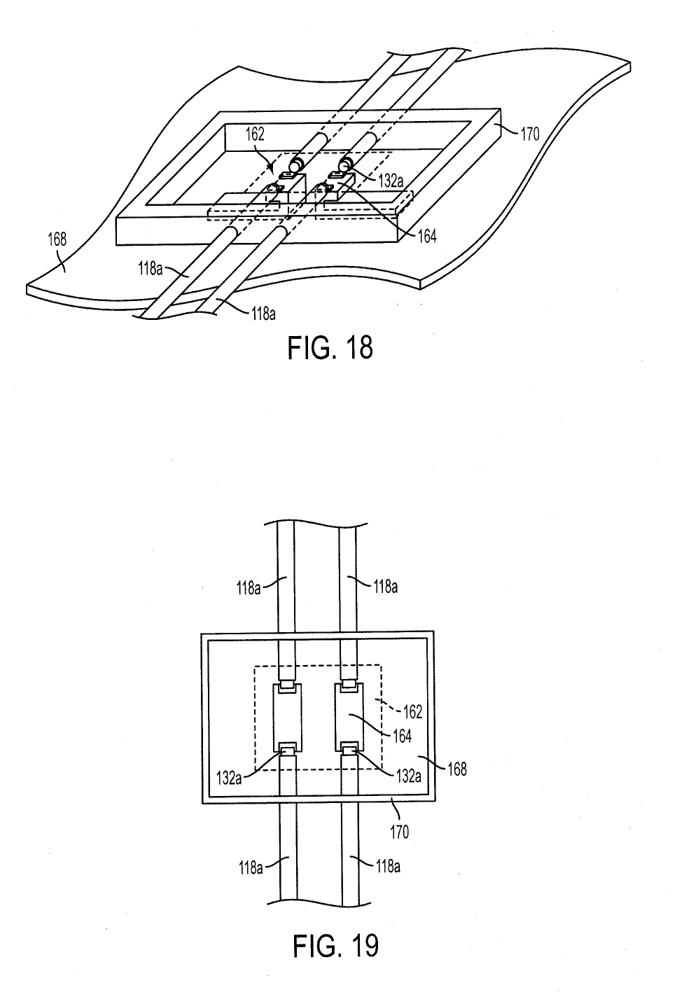

FIG. 18 illustrates yet another embodiment employing a housing 170 in which the conductors 118a of the wiring assembly 90 are segmented. The uninsulated ends 132a of the segments of conductors 118a are electrically connected at their terminal ends directly to the electrical conductors 164 of the module 170 after the housing 170 is secured to the panel glass 168. FIG. 19 illustrates in top plan view the manner in which the uninsulated distal ends of the conductors 118a are available for direct soldering, welding or conductive adhesive affixation to the electrical conductors 164 of a panel 120. Once again, the cavity provided on the interior of housing 170 allows easy access for welding, soldering, or conductive adhesive affixation of the distal ends 132a of conductors 118 to the module conductors 164. After this mechanical and electrical connection is made, the cavity defined by the housing 170 can be filled with a filler material 166, as illustrated in FIGS. 16 and 24C and/or a cover 180 may be affixed to the upper surface of housing 170 to provide a seal.

FIGS. 20-23 illustrate additional embodiments for the housing which also may be used. FIG. 20 illustrates an end view of a housing 170a having grooves 172 on a lower surface of sidewalls thereof for accommodating conductors 118. The grooves can be sized so just a portion of the conductors 118 protrude from a bottom surface of the housing 170, or may be constructed such that the exterior surface of the conductors 118 are on the same plane as the bottom surface of the housing 170. In either case, the housing 170a is mounted on the glass panel 168 of a module 120 with an adhesive and the electrical conductors 118 are mechanically and electrically connected to the electrical conductors 164 of the module 120 through the cavity defined by the peripheral sidewalls of the housing 170a. After the conductors 118 are mechanically and electrically connected to the conductors 164, the cavity defined by the housing 170a can be filled with a filler material 166 and/or a cover 190a can be affixed to the upper surface of the housing 170a to provide a seal.

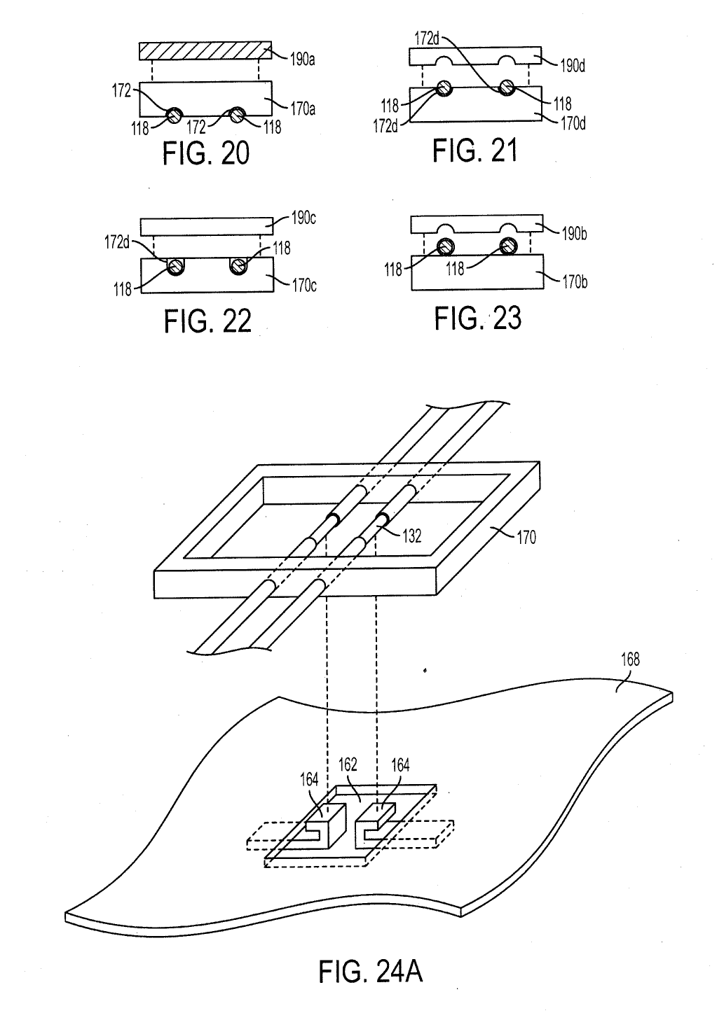

FIG. 21 illustrates another embodiment of a housing in which an upper surface of a housing 170d is provided with grooves 172d to accommodate the electrical conductors 118. Once again, the grooves 172d can be sized so that a portion of the conductors 118 extend above a top surface of the housing 170d or, as illustrated in FIG. 22, the grooves 172d can be deep enough to accommodate the entirety of the conductors. Once the conductors 118 are electrically connected to the conductors 164 of the solar panel, the entire cavity space defined by housing 170d, including an area over the conductors 118, can be filled with a filler material 166 and/or a cover 190d (FIG. 21) or 190c (FIG. 22) can be used to also cover and seal the cavity defined by the housing 170d or 170c.

FIG. 23 illustrates one additional embodiment in which the housing 170b supports on the top surface thereof the conductors 118. The conductors 118 can be bent within the cavity defined area of the housing 170b towards the electrical conductors 164 of the solar module for electrical connection therewith, and the interior cavity defined by the housing 170b can be filled with filler material 166 after conductors 118 are mechanically and electrically connected with conductors 164 of the solar module 120. In this case, a cover 190b can also be provided which has grooves 172b therein to accommodate the conductors 118 and otherwise seal the opening defined by the exterior walls of the housing 170b. Cover 190b can be provided in addition to or in lieu of the filler material 166.

As noted earlier, there are other possible configurations for the wiring assembly 90. FIG. 25 illustrates a wiring assembly 90a which can be used to interconnect a plurality of solar modules 120 in a star configuration. The connection areas 114 are still spaced along the wiring assembly and align with corresponding connection structures 116 of the respective solar modules. In the wire assembly 90a shown in FIG. 25, additional wiring connection areas 200 are provided for making additional mechanical and electrical connections of the conductors in the wiring assembly 90a to properly interconnect the panels 120 in the star configuration. The connection areas 200 can be in the form of a housing similar to housing 170 in which the various conductors 118 of the wiring assembly 90b are brought together and electrically and physically interconnected.

The wiring assembly can also be configured to wire a plurality of solar modules 120 in series, as shown in FIG. 26. FIG. 26 shows a plurality of segmented conductors 118a which respectively interconnect positive and negative conductors 164 of interconnected modules 120 as a single conductive path spanning across the modules 120 and with other segmented conductors 118b, 118c having one end connected to a module and another end have terminating electrical connections 112. Conductor segment 118c can also be arranged to span across the connection areas 116 of the modules 120 and be mechanically fixed to the plates 130, 130a, 130b or housings 170, 170a, 170b, 170c described herein, but without electrical connection to the conductors 164 of a module, as illustrated by the dotted lines in FIG. 26.

In addition, although embodiments illustrated in FIGS. 6A through 25 show a pair of conductors 118 or 118a connected to each module through a connection area 114, it is also possible to have a single segmented conductor 118a at each connection area 114 in the manner shown in FIG. 26.

In all of the embodiments described above, the conductors 118a, 118b, 118c are shown as having an uninsulated portion 132 as part of the wiring assembly 90, 90a or 90b. However, it should be appreciated that the wiring assembly can be constructed without the insulation removed on the conductors 118 in which case the insulation of the conductors 118 can be removed just prior to interconnection of the conductors 118, 118a, 118b to the conductors 164 of a solar module.

As should be evidenced from the foregoing, the wiring assemblies 90, 90a of the invention may be used in a manufacturing facility to pre-wire together solar modules 120 prior to shipment to an installation site, or the wiring assemblies 90, 90a, 90b may be installed in the field on solar modules mounted on a supporting structure.

While various embodiments of the invention have been described and illustrated, it should be appreciated that modifications and changes can be made without parting from the spirit and scope of the invention. Accordingly, the invention is not limited by the foregoing embodiments, but is only limited by the scope of the claims attached.

What is claimed is:

1. A wiring assembly for electrically interconnecting a plurality of solar modules, the wiring assembly comprising:
a plurality of conductors, each conductor terminating with an electrical connection; and
at least one of said plurality of conductors having a plurality of electrical connection structures spaced therealong, each electrical connection structure for enabling an electrical connection with a respective one of the plurality of solar modules.

2. A wiring assembly as in claim 1,wherein each of said conductors has said plurality of electrical connection structures spaced therealong each for enabling an electrical connection of said conductors with a respective one of said plurality of solar modules.

3. A wiring assembly as in claim 1, wherein a connection structure is electrically connected with at least one of said conductors for connecting said at least one conductor to an electrical connection area of a respective solar module.

4. A wiring assembly as in claim 3, wherein said connection structure comprises a housing having sidewalls through which said at least one conductor passes.

5. A wiring assembly as in claim 3, wherein said connection structure comprises a plate formed of an insulating material to which said at least one of said plurality of conductors is secured.

6. A wiring assembly as in claim 3, wherein said at least one conductor has an uninsulated portion at each of said connection structures.

7. A wiring assembly as in claim 1, wherein each said conductor has a single terminating electrical connection at a distal end.

8. A wiring assembly as in claim 3, wherein said connection structure comprises a housing having sidewalls over which said at least one conductor passes.

9. A wiring assembly as in claim 5, wherein each of said plurality of conductors are secured to said plate.

10. A wiring assembly as in claim 5, wherein said plate has an opening therein, said at least one conductor spanning across said opening.

11. A wiring assembly as in claim 4, wherein said at least one conductor passes through opposite sidewalls of said housing and passes through a cavity defined by said housing.

12. A wiring assembly as in claim 11, wherein said connection structure further comprises a cover plate for covering said cavity.

13. A wiring assembly as in claim 11, wherein said housing has at least one groove and said at least one conductor is located in said at least one groove.

14. A wiring assembly as in claim 13, wherein said groove is provided at a lower surface of said opposite sidewalls.

15. A wiring assembly as in claim 13, wherein said groove is provided at an tipper surface of said opposite sidewalls.

16. A wiring assembly as in claim 11, wherein said at least one conductor has an uninsulated portion within said cavity.

17. A wiring assembly as in claim 16, wherein said uninsulated portion is positioned to be co-planar with a bottom surface of said housing.

18. A wiring assembly as in claim 5, wherein said plate has at least one groove therein, and said at least one conductor is positioned within said groove.

19. A wiring assembly as in claim 5, wherein said at least one conductor has an uninsulated portion at said plate.

20. A wiring assembly as in claim 19, wherein said uninsulated portion is positioned to connect with a respective conductor of a solar module.

21. A wiring assembly as in claim 1, wherein said at least one of conductor is formed of conductor segments which are electrically connected in series at a said electrical connection area.

22. A wiring assembly as in claim 1, wherein at least one conductor is formed as a continuous conductor.

23. A wiring assembly as in claim 5, wherein said at least one conductor is secured to said plate by an adhesive.

24. A wiring assembly as in claim 5, wherein said at least one conductor is secured to said plate by a mechanical fastener.

25. A wiring assembly as in claim 5, further comprising at least one support element attached to said plate for supporting said at least one conductor.

26. A wiring assembly as in claim 5, wherein said at least one conductor is segmented, said wiring assembly further comprising a conductive element attached to said plate and to conductive ends of conductor segments.

27. A wiring assembly as in claim 26, wherein said conductive element has insertion holes for receiving conductive ends of conductor segments.

28. A wiring assembly as in claim 5, wherein said plate includes a plurality of grooves and said conductors are located in respective grooves.

29. A wiring assembly as in claim 10, wherein said at least one conductor has a portion bent into said opening.

30. A wiring assembly as in claim 10, wherein said plurality of conductors are secured to said plate and span across said opening.

31. A wiring assembly as in claim 30, wherein said plurality of conductors each has a portion bent into said opening.

32. A wiring assembly as in claim 29, wherein said bent portion is uninsulated.

33. A wiring assembly as in claim 31, wherein said bent portions are uninsulated.

34. A wiring assembly as in claim 1, wherein the spaced electrical connection structures and plurality of conductors are arranged to connect a plurality of solar modules in parallel.

35. A wiring assembly as in claim 1, wherein the spaced electrical connection structures and plurality of conductors are arranged to connect a plurality of solar modules in series.

36. A wiring assembly as in claim 1, wherein the spaced electrical connection structures and plurality of conductors are arranged to connect a plurality of solar modules in a star configuration.

37. A wiring assembly as in claim 8, wherein said at least one conductor spans said cavity and is bent into an area within said cavity toward the bottom of said sidewalls.

38. An apparatus comprising:
a plurality of solar modules; and
a wiring assembly interconnecting said plurality of solar modules, said wiring assembly comprising a plurality of extending conductors, each conductor having a terminal electrical connection, at least one of said conductors having a plurality of spaced connection structures at each of which a respective one of said solar modules is electrically connected to said at least one of said plurality of conductors.

39. An apparatus as in claim 38, wherein said plurality of conductors each have a plurality of spaced connection structures and each of said plurality of spaced connection structures interconnects the conductors of said wiring assembly to respective conductors of said solar modules.

40. An apparatus as in claim 38, wherein said at least one conductor crosses each of said connection structures, said solar modules being electrically connected to said at least one conductor at respective ones of said connection structures.

41. An apparatus as in claim 40, wherein each said connection structure comprises a housing to which said at least one conductor is attached.

42. An apparatus as in claim 40, wherein each said connection structure comprises an insulating plate to which said at least one conductor is attached.

43. An apparatus as in claim 38, wherein said plurality of solar panels are arranged in rows and columns and said at least one conductor of said wiring assembly is electrically connected to a plurality of solar panels in a row.

44. An apparatus as in claim 38, wherein said plurality of solar panels are arranged in rows and columns and said at least one conductor of said wiring assembly is electrically connected to a plurality of solar panels in a column.

45. An apparatus as in claim 38, wherein each of said solar modules has at least one opening through which module conductors pass, said at least one conductor being connected to at least one of said module conductors of each of said solar modules.

46. An apparatus as in claim 38, wherein said at least one conductor comprises a continuous conductor.

47. An apparatus as in claim 38, wherein said at least one conductor comprises a plurality of interconnected segmented conductors.

48. An apparatus as in claim 38, wherein said at least one conductor comprises said plurality of conductors and said plurality of solar modules are each electrically connected to said plurality of conductors.

49. An apparatus as in claim 38, wherein said plurality of solar modules are connected in series by said wiring assembly.

50. An apparatus as in claim 48, wherein said plurality of solar modules are connected in parallel by said wiring assembly.

51. An apparatus as in claim 38, wherein said plurality of solar modules are connected in a star configuration by said wiring assembly.

52. An apparatus as in claim 38, wherein said plurality of solar modules are provided on a carrier which commonly holds said plurality of solar modules as a unit assembly.

53. A method of connecting together a plurality of solar modules, said method comprising:
providing a wiring assembly comprising a plurality of conductors and a plurality of spaced connection structures to which at least one of said conductors is attached; and
electrically connecting at least one conductor of said wiring assembly at each of said spaced connection areas to a respective one of said plurality of solar modules.

54. A method according to claim 53, further comprising electrically connecting a plurality of conductors of said wiring assembly to said plurality of solar modules to provide a parallel electrical connection of said solar modules.

55. A method according to claim 53, further comprising electrically connecting at least one conductor of said wiring assembly to said plurality of solar modules to provide a series electrical connection of said solar modules.

56. A method according to claim 53, further comprising electrically connecting a plurality of conductors of said wiring assembly to said plurality of solar modules to provide a star connection of said solar modules.

57. A method as in claim 53, wherein each of said electrical connection structures is attached to each of said conductors to said at least one conductor.

58. A method as in claim 53, wherein each of said electrical connection structures comprises a housing to which said at least one conductor is attached, said method further comprising attaching each said housing to a respective solar module at a location corresponding to electrical connections of said respective solar module and electrically connecting at least one conductor to a respective solar module through a cavity defined by said housing.

59. A method as in claim 53, wherein each of said electrical connection structures comprises an insulated plate, said method further comprising attaching each said plate to a respective solar module at a location corresponding to electrical connections of said respective solar module.

60. A method of claim 58, further comprising sealing said cavity defined by a said housing after an electrical connection is made between said at least one conductor and a solar module.

61. A method of claim 59, further comprising sealing an area between said plate and a solar module after an electrical connection is made between said at least one conductor and a solar module.

62. A method as in claim 59, wherein each plate has an opening through which said electrical connection is made, said method further comprising sealing said opening after said electrical connection is made.
